(19) United States
(12) Patent Application Publication
(10) Pub. No.: US 2025/0294720 A1
(43) Pub. Date: Sep. 18, 2025

(54) SEMICONDUCTOR DEVICES

(71) Applicant: Samsung Electronics Co., Ltd., Suwon-si (KR)

(72) Inventors: Sungjoon PARK, Suwon-si (KR); Masayuki TERAI, Suwon-si (KR)

(73) Assignee: Samsung Electronics Co., Ltd., Suwon-si (KR)

(21) Appl. No.: 18/941,473

(22) Filed: Nov. 8, 2024

(30) Foreign Application Priority Data
Mar. 14, 2024 (KR) 10-2024-0035685

(51) Int. Cl. H10B 12/00

(52) U.S. Cl. CPC H10B 12/315; H10B 12/05; H10B 12/50

(57) ABSTRACT

An embodiment of the present inventive concepts provides a semiconductor device, including: a bit line extending in a first horizontal direction; an intermediate insulating layer on at least one side of the bit line and extending in the first horizontal direction; a channel structure comprising a lower portion on the bit line and the intermediate insulating layer and an upper portion extending upwardly from the lower portion; and a word line on the lower portion of the channel structure and extending across the bit line in a second horizontal direction, intersecting the first horizontal direction, wherein the lower portion of the channel structure comprises a first portion covering an upper surface of the bit line and a second portion extending downwardly from one end of the first portion and covering at least a portion of the side surface of the bit line on the intermediate insulating layer.

### CROSS-REFERENCE TO RELATED APPLICATION(S)

This application claims benefit of priority to Korean Patent Application No. 10-2024-0035685 filed on Mar. 14, 2024 in the Korean Intellectual Property Office, the disclosure of which is incorporated herein by reference in its entirety.

### BACKGROUND

The present inventive concepts relate to a semiconductor device.

With an increase in demand for high performance, high speed, and/or multi-functionalization of semiconductor devices, the degree of integration of semiconductor devices is increasing. As such, in manufacturing semiconductor devices having a fine pattern corresponding to the tendency for high integration of semiconductor devices, there is need for implementation of patterns having a fine width and/or a fine separation distance.

### SUMMARY

An aspect of the present inventive concepts is to provide a semiconductor device with advantageously enhanced on current by increasing a contact area between a bit line and a channel structure.

According to an aspect of the present inventive concepts, a semiconductor device includes: a bit line extending in a first horizontal direction; an intermediate insulating layer on at least one side of the bit line and extending in the first horizontal direction such that the intermediate insulating layer is in contact with at least a portion of a side surface of the bit line; a channel structure comprising a lower portion and an upper portion, the lower portion of the channel structure on the bit line and the intermediate insulating layer, and the upper portion of the channel structure extending upwardly from one end of the lower portion; and a word line on the lower portion of the channel structure and extending across the bit line in a second horizontal direction, the second horizontal direction intersecting the first horizontal direction, wherein the lower portion of the channel structure comprises a first portion covering an upper surface of the bit line and a second portion extending downwardly from one end of the first portion and covering at least a portion of the side surface of the bit line on the intermediate insulating layer.

According to an aspect of the present inventive concepts, a semiconductor device includes: a bit line extending in a first horizontal direction; an intermediate insulating layer extending in the first horizontal direction from at least one side of the bit line and having an upper surface at a level lower than an upper surface of the bit line; a channel structure comprising a lower portion and an upper portion, the lower portion of the channel structure on the bit line and the intermediate insulating layer, and the upper portion of the channel structure extending upwardly from one end of the lower portion, the lower portion of the channel structure further comprising a first line portion covering the upper surface of the bit line, and a second line portion extending downwardly from one end of the first line portion and covering a side surface of the bit line on the intermediate insulating layer; a word line on the lower portion of the channel structure and extending across the bit line in a second horizontal direction, the second horizontal direction intersecting the first horizontal direction; and a dielectric structure extending in the second horizontal direction across the bit line and the intermediate insulating layer, wherein the dielectric structure covers an external surface of the lower portion of the channel structure and at least a portion of an upper surface of the intermediate insulating layer.

According to an aspect of the present inventive concepts, a semiconductor device includes: a lower insulating layer; a bit line on the lower insulating layer; an intermediate insulating layer on a side surface of a lower region of the bit line; a channel structure on the bit line; a word line on the channel structure such that a side surface of the word line faces a side surface of the channel structure; a dielectric structure between the word line and the channel structure; and a pad structure on the channel structure, wherein the bit line comprises a first conductive layer, a second conductive layer and a third conductive layer, sequentially stacked, and the channel structure is in contact with an upper surface and a side surface of the third conductive layer.

### BRIEF DESCRIPTION OF DRAWINGS

The above and other aspects, features, and advantages of the present inventive concepts will be more clearly understood from the following detailed description, taken in conjunction with the accompanying drawings, in which:

FIG. 1 is a plan view of a semiconductor device according to at least one example embodiment;

FIGS. 2 and 3A are cross-sectional views illustrating semiconductor devices according to example embodiments;

FIG. 3B is an enlarged view of a portion of the semiconductor device illustrated in FIG. 3A;

FIGS. 4A to 4C are partial enlarged views of semiconductor devices according to example embodiments;

FIG. 5 is a plan view of a semiconductor device according to at least one example embodiment;

FIG. 6 is a cross-sectional view illustrating a semiconductor device according to at least one example embodiment;

FIGS. 7A to 22B are vertical cross-sectional views illustrated according to a process order to explain a method of manufacturing a semiconductor device according to at least one example embodiment; and

FIG. 23 is a schematic of an electronic device according to at least one embodiment.

### DETAILED DESCRIPTION

Hereinafter, example embodiments of the present inventive concepts will be described with reference to the accompanying drawings. It will be understood that, when the terms “approximately” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “approximately” or “substantially,” it will be understood that these values should be construed as including a manufacturing or operational tolerance (e.g., +10%) around the stated numerical values and/or geometry.

Furthermore, it will be understood that when a material layer is referred to as being “on” or “above” a substrate or another layer, it can be directly on the substrate or the other layer, or intervening layers may also be present. It will also be understood that such spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly. Furthermore, in the following embodiments, a material included in each layer is an example, and another material may be used in addition to or instead of the material.

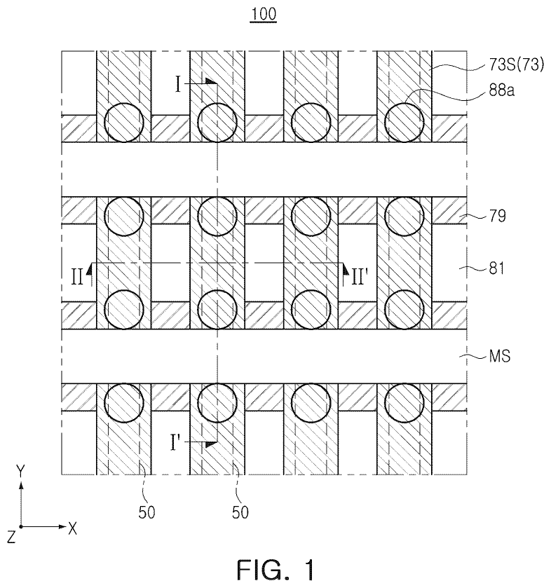

FIG. 1 is a plan view of a semiconductor device according to at least one example embodiment.

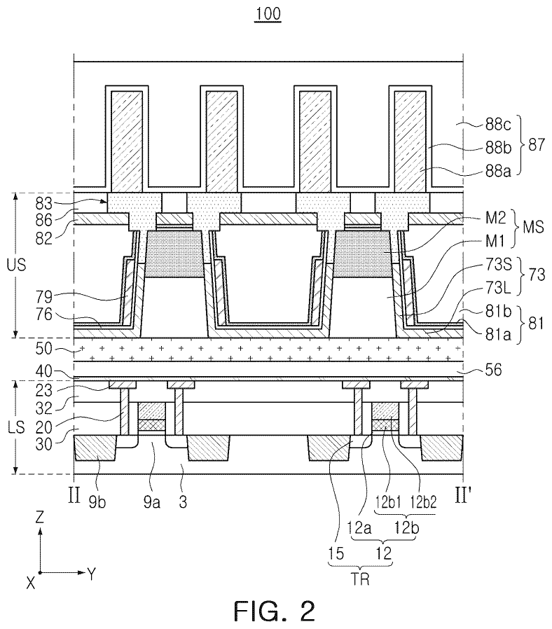

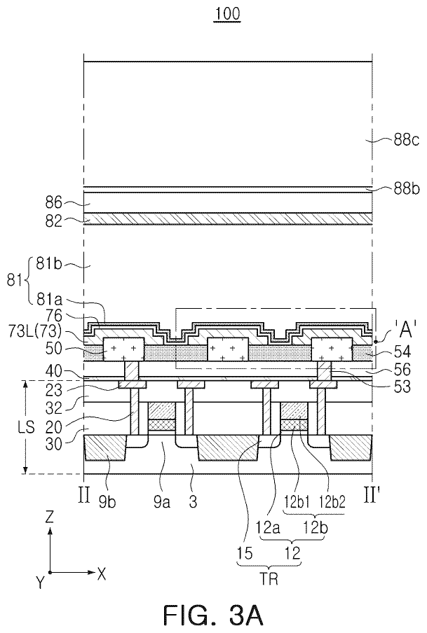

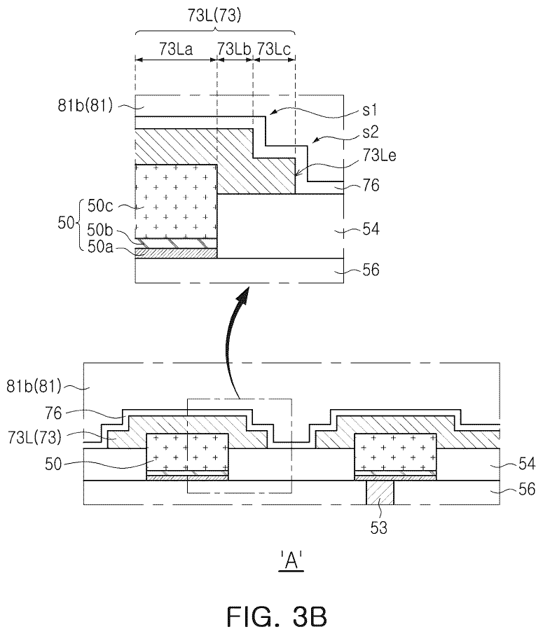

FIGS. 2 and 3A are cross-sectional views illustrating semiconductor devices according to example embodiments. FIG. 2 is a vertical cross-sectional view taken along line I-I′ of the semiconductor device shown in FIG. 1. FIG. 3A is a vertical cross-sectional view taken along line II-II′ of the semiconductor device illustrated in FIG. 1.

FIG. 3B is an enlarged view of a portion of the semiconductor device illustrated in FIG. 3A. FIG. 3B may be an enlarged view in which a first upper insulating layer 81a is not shown for convenience of explanation.

Referring to FIGS. 1 to 3B, a semiconductor device 100 according to at least one example embodiment of the present disclosure may include a lower structure LS, a bit line 50, an upper structure US, and an information storage structure 87.

The lower structure LS may include a substrate 3, a circuit element TR, a peripheral plug 20, a peripheral interconnection 23, a first peripheral insulating layer 30, and a second peripheral insulating layer 32.

The substrate 3 may include a semiconductor material, such as a Group IV semiconductor, a Group III-V compound semiconductor, a Group II-VI compound semiconductor, and/or the like. For example, the Group IV semiconductor may include silicon, germanium, or silicon-germanium. The substrate 3 may be a silicon substrate, a silicon on insulator (SOI) substrate, a germanium substrate, a germanium on insulator (GOI) substrate, a silicon-germanium substrate, and/or a substrate including an epitaxial layer.

The circuit element TR may include a word line driver, a sense amplifier, row and column decoders, and control circuits. The circuit element TR may include a peripheral transistor. For example, the peripheral transistor may include a gate structure 12 disposed on a peripheral active region 9a limited by a device isolation region 9b in the substrate 3, and peripheral source/drain regions 15 disposed within the peripheral active region 9a on both sides of the gate structure 12.

The gate structure 12 may include a peripheral gate electrode 12b and a peripheral gate dielectric layer 12a between the peripheral gate electrode 12b and the peripheral active region 9a. The peripheral gate electrode 12b may include at least two conductive layers, for example, a first conductive layer 12b1 and a second conductive layer 12b2 on the first conductive layer 12b1.

A peripheral plug 20 may be connected to a corresponding peripheral source/drain region 15 and extend vertically, and the peripheral interconnection 23 may be disposed on the peripheral plug 20. The peripheral interconnection 23 may be electrically connected to the circuit element TR through the peripheral plug 20. A first peripheral insulating layer 30 may surround side surfaces of the peripheral gate electrode 12b and the peripheral plug 20. A second peripheral insulating layer 32 may be disposed on the first peripheral insulating layer 30 and may surround the peripheral plug 20 and the peripheral interconnection 23. An upper surface of the second peripheral insulating layer 32 may be coplanar with an upper surface of the peripheral interconnection 23.

In at least one example embodiment, the peripheral plug 20 and the peripheral interconnection 23 may include a metal layer and a barrier layer configured to cover a side surface and a lower surface of the metal layer. The barrier layer may include at least one of TiN, TaN, WN, TiSiN, TaSiN, RuTiN, and/or the like; and the metal layer may include a metal material such as W, Mo, and/or the like. The first peripheral insulating layer 30 and the second peripheral insulating layer 32 may include silicon oxide, silicon nitride, silicon oxynitride, a low-κ dielectric, and/or a combination thereof.

The semiconductor device 100 may further include an etch stop layer 40 disposed on the lower structure LS. The etch stop layer 40 may cover the peripheral interconnection 23 and the second peripheral insulating layer 32. The etch stop layer 40 may include SiBN, SiCN, SiN, a combination thereof, and/or the like.

The bit line 50 may be disposed on the lower structure LS. The bit lines 50 may extend in a Y-direction and may be spaced apart from each other in an X-direction. The semiconductor device 100 may further include a bit line plug 53 disposed below the bit line 50, and a lower insulating layer 56 surrounding the bit line 50 and the bit line plug 53. The bit line 50 may be electrically connected to the circuit element TR of the lower structure LS, for example, a sensor amplifier, via the bit line plug 53.

The bit line 50 may include a plurality of conductive patterns. In at least one example embodiment, the bit line 50 may include first to third conductive patterns 50a, 50b and 50c, sequentially stacked on the lower insulating layer 56. The first conductive pattern 50a may include a metal material such as titanium (Ti), tantalum (Ta), tungsten (W) and aluminum (Al). The second conductive pattern 50b may include, for example, a metal nitride such as titanium nitride (TiN) or a silicide material such as titanium silicide (TiSi). The third conductive pattern 50c may include a semiconductor material such as polycrystalline silicon. The third conductive pattern 50c may be a layer doped with impurities. However, materials, numbers of layers and thicknesses of the layers forming the bit line 50 may vary depending on embodiments. The bit line plug 53 may include the same material as the peripheral plug 20 and the peripheral interconnection 23. The lower insulating layer 56 may include silicon oxide, silicon nitride, silicon oxynitride, a low-κ dielectric material, or a combination thereof.

The upper structure US may be disposed on the bit line 50. The upper structure US may include a mold structure MS, an intermediate insulating layer 54, a channel structure 73, a word line 79, an upper insulation structure 81, an upper capping layer 82, and a landing pad structure 83.

The mold structure MS may be disposed on the bit line 50. In a plan view, the mold structures MS may extend in the X-direction and may be spaced apart from each other in the Y-direction. The mold structure MS may include a lower mold layer M1 and an upper mold layer M2. The upper mold layer M2 may be disposed on the lower mold layer M1, and the lower mold layer M1 and the upper mold layer M2 may extend in the X-direction.

The lower mold layer M1 and the upper mold layer M2 may include an insulator material, such as silicon oxide, silicon nitride, silicon oxynitride, a combination thereof, and/or the like. In at least one example embodiment, the lower mold layer M1 and the upper mold layer M2 may include different materials. For example, the lower mold layer M1 may include silicon oxide, and the upper mold layer M2 may include silicon nitride.

The intermediate insulating layer 54 (or ‘bit line insulating layer’ or ‘middle insulating layer’) may be disposed on at least one side of the bit line 50 and extend in the Y-direction. Referring to FIG. 3B, a lower surface of the middle insulating layer 54 may be in contact with an upper surface of the lower insulating layer 56. An upper surface of the middle insulating layer 54 may be at a level lower than an upper surface of the bit line 50. Accordingly, the intermediate insulating layer 54 may be in contact with at least a portion of a side surface of the bit line 50, and a portion of the remaining side surface of the bit line 50 may be in contact with the channel structure 73. The intermediate insulating layer 54 may include silicon oxide, silicon nitride, silicon oxynitride, a low-κ dielectric material, a combination thereof, and/or the like. The middle insulating layer 54 may include a material different from that of the lower insulating layer 56. For example, the lower insulating layer 56 may include silicon oxide or a low-κ dielectric material, while the middle insulating layer 54 may include silicon nitride.

As mentioned above, the bit line 50 may include a plurality of bit lines 50 parallel to each other. A plurality of the intermediate insulating layers 54 may be arranged to be alternately arranged with the plurality of bit lines 50. For example, each of the plurality of intermediate insulating layers 54 may be disposed between a pair of adjacent bit lines of the plurality of bit lines 50.

The channel structure 73 may be disposed on the bit line 50. The channel structure 73 may include a lower portion 73L in contact with and electrically connected to the bit line 50 and an upper portion part 73S extending upwardly from one end of the lower portion 73L in the Y-direction. The upper portion 73S may be referred to as a vertical channel portion.

Referring to FIGS. 3A and 3B, the lower portion 73L may be defined as including a first portion 73La covering the upper surface of the bit line 50, a second portion 73 Lb extending downwardly from one end of the first portion 73La along the side surface of the bit line 50, and a third portion 73Lc extending horizontally from one end of the second portion 73 Lb along an upper surface of the intermediate insulating layer 54. The third portion 73Lc may have an end portion 73Le on the intermediate insulating layer 54. For example, in a plan view, a plurality of channel structures 73 may be spaced apart from each other in the X-direction. In some cases, the first portion 73La may be referred to as a first line portion, and the second portion 73 Lb and the third portion 73Lc may be collectively referred to as a second line portion.

As the second portion 73 Lb of the channel structure extends downwardly from the one end of the first portion 73La and covers the side surface of the bit line 50, a contact area between the channel structure 73 and the bit line 50 can be increased, whereby a reliability of an on-current can be advantageously enhanced.

Referring to FIG. 2, the upper portion 73S may extend upwardly along a side surface of the mold structure MS from one end of the lower portion 73L. The upper portion 73S may extend in a direction oblique to a vertical direction (Z-direction), but the present inventive concepts are not limited thereto.

The channel structure 73 may be formed of a semiconductor material such as silicon. The channel structure 73 may be formed of single crystalline silicon or polysilicon. However, the channel structure 73 is not limited to semiconductor materials such as silicon, but may be formed of other semiconductor materials that may be used as a channel region of a transistor. For example, the channel structure 73 may include an oxide semiconductor layer, a two-dimensional material layer, and/or the like that can be used as a channel region of a transistor.

The oxide semiconductor layer may be indium gallium zinc oxide (IGZO). However, the present inventive concepts are not limited thereto. For example, the oxide semiconductor layer may include at least one of indium tungsten oxide (IWO), indium tin gallium oxide (ITGO), indium aluminum zinc oxide (IAGO), indium gallium oxide (IGO), indium tin zinc oxide (ITZO), zinc tin oxide (ZTO), indium zinc oxide (IZO), ZnO, indium gallium silicon oxide (IGSO), indium oxide (InO), tin oxide (SnO), titanium oxide (TiO), zinc oxynitride (ZnON), magnesium zinc oxide (MgZnO), indium zinc oxide (ZnO), indium zinc oxide (ZnO), indium gallium zinc oxide (InGaZnO)), zirconium indium zinc oxide (ZrInZnO), hafnium indium zinc oxide (HfInZnO), tin indium zinc oxide (SnInZnO), aluminum tin indium zinc oxide (AlSnInZnO), silicon indium zinc oxide (SiInZnO), zinc tin oxide (ZnSnO), aluminum zinc tin oxide (AlZnSnO), gallium zinc tin oxide (GaZnSnO),zirconium zinc tin oxide (ZrZnSnO), indium gallium silicon oxide (InGaSiO), etc.

The two-dimensional material layer may include at least one of a transition metal dichalcogenide material layer, a black phosphorous material layer, and a hexagonal Boron-Nitride (hBN) material layer, which may have semiconductor characteristics. For example, the two-dimensional material layer may include at least one of BiOSe, Crl, WSe2, MoS2, TaS, WS, SnSe, ReS, β-SnTe, MnO, AsS, P (black), InSe, h-BN, GaSe, GaN, SrTiO, MXene, and Janus 2D materials, which may form a two-dimensional semiconductor material.

A dielectric structure 76 may extend in the X-direction across the bit line 50 and the middle insulating layer 54 on the bit line 50 and the middle insulating layer 54.

Referring to FIG. 3B, the dielectric structure 76 may extend in the X-direction while covering at least a portion of a surface of the lower portion 73L of the channel structure and the upper surface of the intermediate insulating layer 54. The dielectric structure 76 on the lower portion 73L of the channel structure may have a plurality of step portions s1 and s2. The first step portion s1 may be positioned on the second portion 73 Lb of the lower portion73L, and the second step portion s2 may be located on the third portion 73Lc of the lower portion 73L.

Referring to FIG. 3A, the dielectric structure 76 may extend upwardly from one end of the lower portion 73L of the channel structure along between the upper portion 73S of the channel structure and the word line 79. An upper surface of the dielectric structure 76 may be at substantially the same level as an upper surface of the mold structure MS, but the present inventive concepts are not limited thereto.

The dielectric structure 76 may be a tunnel dielectric layer that does not include an information storage layer. For example, the entire dielectric structure 76 may include at least one of silicon oxide and a high-k dielectric. The high-K dielectric may include a metal oxide and/or a semimetal oxide. For example, the high-K dielectric may be formed of HfO₂, HfSiO, HfSiON, HfTaO, HfTIO, HfZrO, ZrO₂, Al₂O₃, or a combination thereof, but the present disclosure not limited thereto. The dielectric structure 76 may be formed of a single layer or multiple layers of the materials described above.

In another example, the dielectric structure 76 may include an information storage layer and a dielectric layer. For example, the dielectric structure 76 may have polarization properties depending on an electrical field and may include a ferroelectric layer that may have remnant polarization by a dipole even without an external electrical field. Data may be recorded using such a polarization state in the ferroelectric layer. Accordingly, the dielectric structure 76 may include a ferroelectric layer that may be referred to as an information storage layer. The ferroelectric layer that may be the information storage layer may include an Hf-based compound, a Zr-based compound, and/or an Hf-Zr -based compound including a ferroelectric material phase. For example, the Hf-based compound may be an HfO-based ferroelectric material, the Zr-based compound may include a ZrO-based ferroelectric material, and the Hf-Zr -based compound may include a hafnium zirconium oxide (HZO)-based ferroelectric material. The ferroelectric layer that may be the information storage layer may include impurities, such as a ferroelectric material doped with at least one of C, Si, Mg, Al, Y, N, Ge, Sn, Gd, La, Sc, and Sr. For example, the ferroelectric layer that may be the information storage layer may be a material in which at least one of HfO₂, ZrO₂ and HZrO is doped with impurities, (e.g., at least one of C, Si, Mg, Al, Y, N, Ge, Sn, Gd, La, Sc and Sr) and has a ferroelectric material phase.

In the dielectric structure 76, the information storage layer is not limited to the aforementioned material types, and may include any material configured for storing information.

When viewed in a plan view, the word lines 79 may intersect the bit lines 50. For example, the word lines 79 may extend along the side surfaces of the mold structures MS in the X-direction, and may be spaced apart from each other in the Y-direction. The word line 79 may be disposed on the channel structure 73. For example, the word line 79 may be disposed on the lower portion 73L of the channel structure 73 and overlap the upper portion 73S of the channel structure 73 in the vertical direction. An upper end of the word line 79 may be positioned on a lower level than that of the upper surface of the mold structure MS.

Upper insulating structures 81 may be disposed between adjacent mold structures MS and may cover the word lines 79, respectively. The upper insulating structures 81 may extend in the X-direction and may be spaced apart from each other in the Y-direction. The upper insulating structures 81 may be alternately disposed with the mold structures MS in the Y-direction.

The upper insulation structure 81 may include a first upper insulation layer 81a and a second upper insulation layer 81b. The first upper insulating layer 81a may be conformally disposed along surfaces of the bit line 50, the channel structure 73, the dielectric structure 76, and the word line 79. The second upper insulating layer 81b may be disposed on the first upper insulating layer 81a and may fill a space between the mold structures MS. In at least one example embodiment, a portion of the first upper insulating layer 81a may cover a portion of a dielectric structure covering an upper surface of the upper mold layer M2. The first upper insulating layer 81a and the second upper insulating layer 81b may include silicon oxide, silicon nitride, silicon oxynitride, a low dielectric, or a combination thereof. For example, the first upper insulating layer 81a may include silicon nitride, and the second upper insulating layer 81b may include silicon oxide.

The upper capping layer 82 may cover the mold structure MS and the upper insulating structure 81 and may extend in a horizontal direction. The upper capping layer 82 may be in contact with an upper surface of the first upper insulating layer 81a and an upper surface of the second upper insulating layer 81b. The upper capping layer 82 may include silicon nitride.

The landing pad structure 83 may be disposed on the channel structure 73 and may penetrate through the upper capping layer 82 to be in contact with the upper portion 73S of the channel structure 73. The landing pad structure 83 may be electrically connected to the bit line 50 through the channel structure 73.

The landing pad structure 83 may include a pad portion, a connection portion, and a contact portion. The pad portion may refer to a portion of the landing pad structure 83 disposed on the upper capping layer 82, and may be in contact with a first electrode 88a of the information storage structure 87 described below. The connection portion may be disposed below the pad portion and may vertically penetrate through the upper capping layer 82. For example, the connection portion may refer to a portion of the landing pad structure 83 disposed between a lower surface of the pad portion and the upper surface of the mold structure MS. The contact portion may be disposed below the connection portion and may be in contact with an upper surface of the channel structure 73. For example, the contact portion may refer to a portion of the landing pad structure 83 disposed between the upper mold layer M2 of the mold structure MS and an upper end of the dielectric structure 76.

The landing pad structure 83 may include a metal layer and a barrier layer (not shown) covering a lower surface of the metal layer. The metal layer may include a metal material such as W or Mo, and the barrier layer may include at least one of TiN, TaN, WN, TiSiN, TaSiN, or RuTiN.

In at least one example, the information storage structure 87 may be a capacitor configured to store information in a DRAM. For example, the dielectric layer 88b of the information storage structure 87 may be a capacitor dielectric layer of the DRAM, and the dielectric layer 88b may include a high-K dielectric material, silicon oxide, silicon nitride, silicon oxynitride, a combination thereof, and/or the like.

In another example, the information storage structure 87 may be a structure configured to store information of a memory different from the DRAM. For example, the information storage structure 87 may be a capacitor of a ferroelectric memory (FeRAM). For example, the dielectric layer 88b may be a ferroelectric layer configured to record data using a polarization state. In another example, the dielectric layer 88b may include a lower dielectric layer and a ferroelectric layer on the lower dielectric layer. Here, the lower dielectric layer may include at least one of silicon oxide, silicon oxynitride, silicon nitride, and a high-K dielectric.

In at least one example embodiment, when the dielectric structures 76 include an information storage layer, the information storage structure 87 may be omitted.

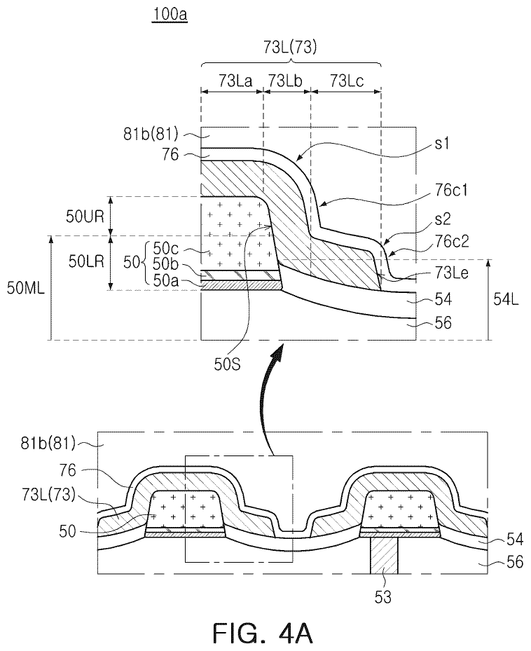

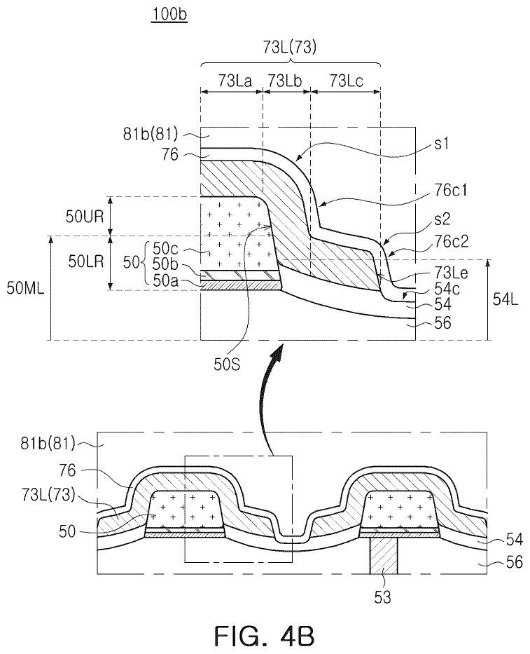

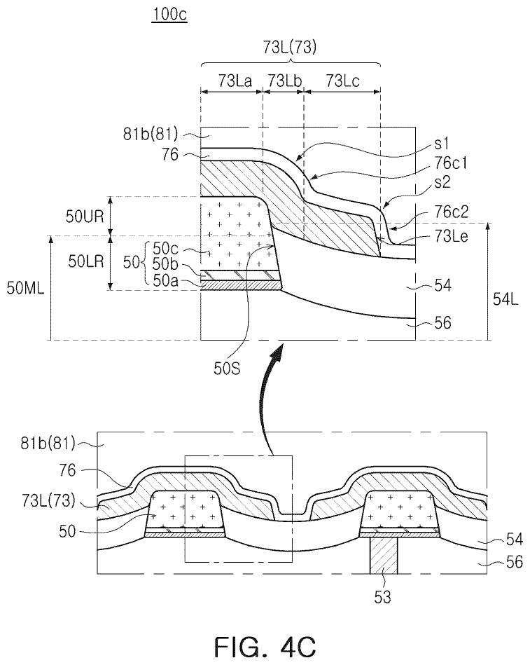

FIGS. 4A to 4C are partial enlarged views of semiconductor devices according to example embodiments.

Referring to FIG. 4A, a semiconductor device 100a may be identical or substantially similar to those descried in FIGS. 1 to 3B, except that a side surface 50S of the bit line 50 has an inclined or curved shape with respect to a lower surface of the bit line 50 and an intermediate insulating layer 54 is positioned below a middle level 50ML of the bit line 50.

The bit line 50 of the semiconductor device 100a may have the side surface 50S inclined with respect to the lower surface of the bit line 50. In another aspect, a horizontal width of the bit line 50 in the X-direction may increase as it approaches from the upper surface of the bit line 50 to the lower surface of the bit line 50. Accordingly, the second portion 73 Lb of the lower portion 73L of the channel structure 73 may also have a side surface inclined with respect to a lower surface of the lower insulating layer 56.

An upper region of the side surface 50S of the bit line 50 may have an upwardly curved shape. The upper area of the side surface 50S of the bit line 50 may be defined as a region extending from the upper surface of the bit line 50 to an inclined portion of the side surface 50S. Accordingly, an upper region of the second portion 73 Lb of the lower portion 73L of the channel structure 73 may also have an upwardly curved shape.

In the semiconductor device 100a, the intermediate insulating layer 54 may have a downwardly curved shape. In another aspect, the lower and upper surfaces of the intermediate insulating layer 54 may have a downwardly curved shape. Accordingly, lower surfaces of the second portion 73 Lb and a third portion 73Lc of the lower portion 73L of the channel structure 73 may also have a downwardly curved shape. Meanwhile, a surface of the end portion 73Le of the third portion 73Lc positioned on the middle insulating layer 54 may be inclined with respect to the upper surface of the middle insulating layer 54.

In the meantime, an uppermost level 54L of the middle insulating layer 54 may be positioned below the middle level 50ML of the bit line 50, where the middle level 50ML of the bit line 50 may be defined as a level located in a middle between levels of the upper and lower surfaces of the bit line 50. Based on the middle level 50ML, the bit line 50 may be defined as having an upper region 50UR positioned there above and a lower region 50LR positioned there below. Accordingly, the middle insulating layer 54 may be in contact with an external side surface of the lower region 50LR of the bit line 50.

External side surfaces of a plurality of step portions s1 and s2 of a dielectric structure 76 may have an upwardly curved shape. Furthermore, the dielectric structure 76 on the second portion 73 Lb may have an inclined portion 76c1, and the dielectric structure 76 on the third portion 73Lc may have an inclined portion 76c2.

Referring to FIG. 4B, a semiconductor device 100b may be identical or substantially similar to those described in FIGS. 1 to 4A, except that the intermediate insulating layer 54 has a concave portion 54c that is concave downwardly in an upper region thereof.

The middle insulating layer 54 may have the concave portion 54c that is recessed downwardly near the surface of the end portion 73Le of a third portion 73Lc of a channel structure 73. An external surface of the concave portion 54c of the intermediate insulating layer 54 may be a surface continuously extending from the surface of the end portion 73Le of the third portion 73Lc. The concave portion 54c of the middle insulating layer 54 may extend in the Y-direction on at least one side of the bit line 50.

A dielectric structure 76 may include a portion filling the concave portion 54c of the intermediate insulating layer 54. Accordingly, the lower surface of the dielectric structure 76 may be located on a level lower than a lowermost level of the channel structure 73.

Referring to FIG. 4C, a semiconductor device 100c may be identical or substantially similar to those described in FIGS. 1 to 4B, except that the middle insulating layer 54 is positioned above the middle level 50ML of a bit line 50.

The uppermost level 54L of the middle insulating layer 54 may be positioned above the middle level 50ML of the bit line 50. Accordingly, the middle insulating layer 54 may be in contact with an external side surface of the upper region 50UR of the bit line 50.

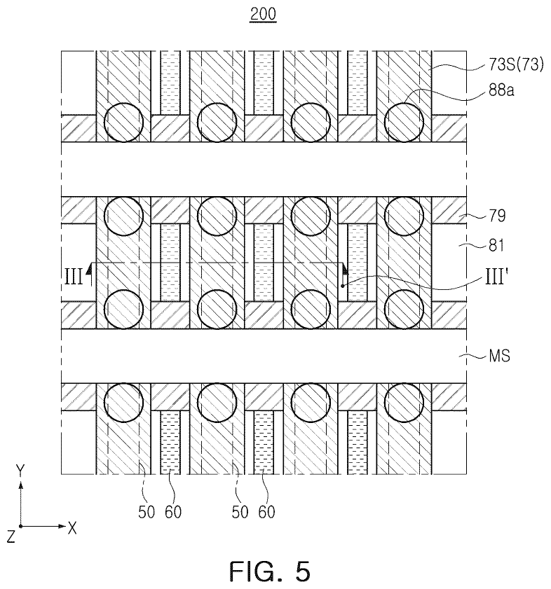

FIG. 5 is a plan view of a semiconductor device according to at least one example embodiment.

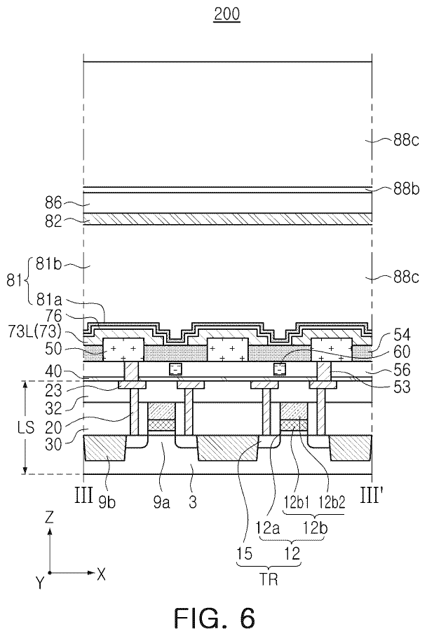

FIG. 6 is a cross-sectional view illustrating a semiconductor device according to at least one example embodiment. FIG. 6 is a vertical cross-sectional view taken along line III-III′ of the semiconductor device shown in FIG. 5.

Referring to FIGS. 5 and 6, the semiconductor device 200 according to at least one embodiment of the present inventive concepts may be identical or substantially similar to those described in FIGS. 1 to 4B, except for further including shield patterns 60.

The semiconductor device 200 may further include the shield patterns 60 extending in the Y-direction and spaced apart from each other in the X-direction. The shield patterns 60 may be alternately disposed with the bit lines 50 in the X-direction. A lower surface of the shield pattern 60 may be disposed on a lower level than that of the lower surface of the bit line 50, and an upper surface of the shield pattern 60 may be disposed on a lower level than the upper surface of the bit line 50. The shield patterns 60 may reduce capacitance between the bit lines 50.

The shield pattern 60 may include doped polysilicon, metal, conductive metal nitride, a metal-semiconductor compound, a metal compound, conductive metal oxide, graphene, a carbon nanotube, or a combination thereof.

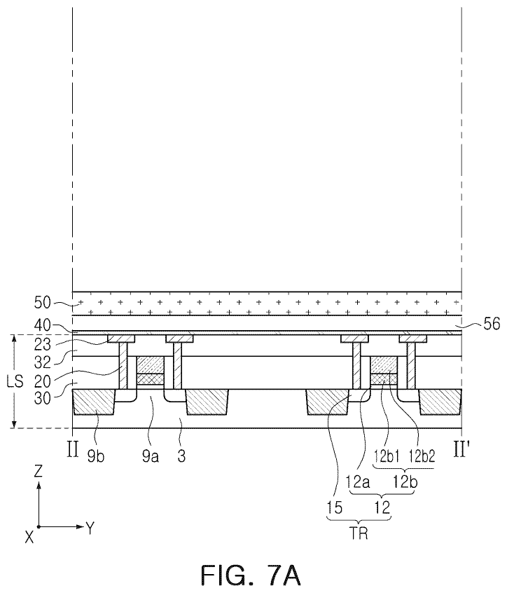

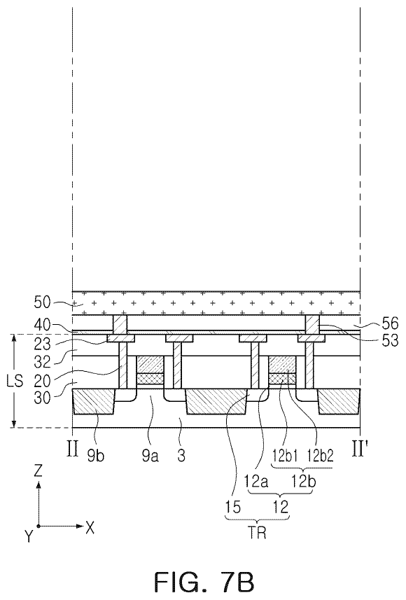

FIGS. 7A to 20 are vertical cross-sectional views illustrated according to a process order to explain a method of manufacturing a semiconductor device according to at least one example embodiment.

Specifically, FIGS. 7A, 8A, 9A, 10A, 11A, 12A, 13A, 14A, 15A, 16A, 17, 18, 19, and 20 are vertical section views corresponding to FIG. 2. FIGS. 7B, 8B, 9B, 10B, 11B, 12B, 13B, 14B, 15B, 16B, 17, 18, 19, 20, and 21 are vertical cross-sectional views corresponding to FIG. 3A.

Referring to FIGS. 7A and 7B, a lower structure LS may be formed. The lower structure LS may include a substrate 3, a circuit element TR on the substrate 3, a peripheral interconnection 23 and a peripheral plug 20 electrically connected to the circuit element TR, a first peripheral insulating layer 30 surrounding a side surface of the peripheral plug 20 and a side surface of the circuit element TR, and a second peripheral insulating layer 32 surrounding the peripheral interconnection 23 and the peripheral plug 20, as described above with reference to FIGS. 2 and 3A.

An etch stop layer 40 and a lower insulating layer 56 may be formed on the lower structure LS. The etch stop layer 40 may cover the peripheral interconnection 23 and the second peripheral insulating layer 32. The lower insulating layer 56 may cover the etch stop layer 40.

A bit line 50 and a bit line plug 53 may be formed on the etch stop layer 40 and the lower insulating layer 56. For example, the bit line plug 53 may be formed to penetrate through the etch stop layer 40 and the lower insulating layer 56 to be in contact with the peripheral interconnection 23, and the bit line 50 may be formed on the bit line plug 53.

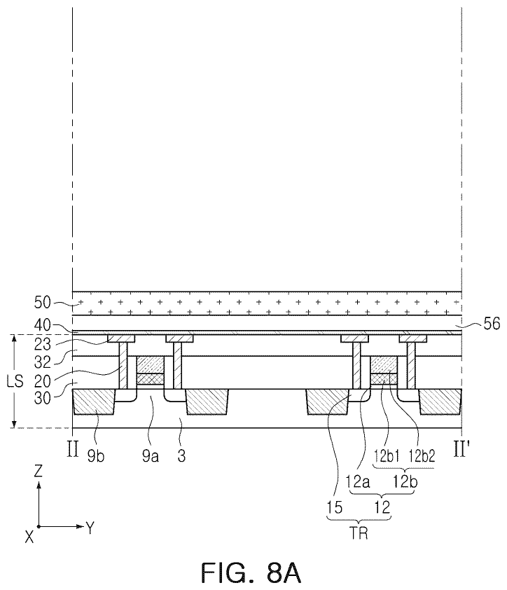

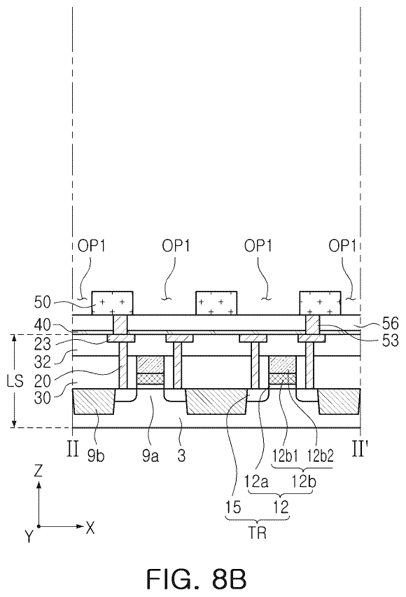

Referring to FIGS. 8A and 8B, the bit line 50 may be patterned to form a plurality of bit lines 50 spaced apart from each other in an X-direction.

After forming a predetermined mask layer on the bit line 50, openings OP1 that allow an upper surface of the lower insulating layer 56 to be exposed may be formed using the mask layer. The predetermined mask layer may be, for example, a photoresist layer.

The openings OP1 may be formed to be spaced apart from each other in the X-direction, and accordingly, the bit lines 50 may be spaced apart from each other in the X-direction.

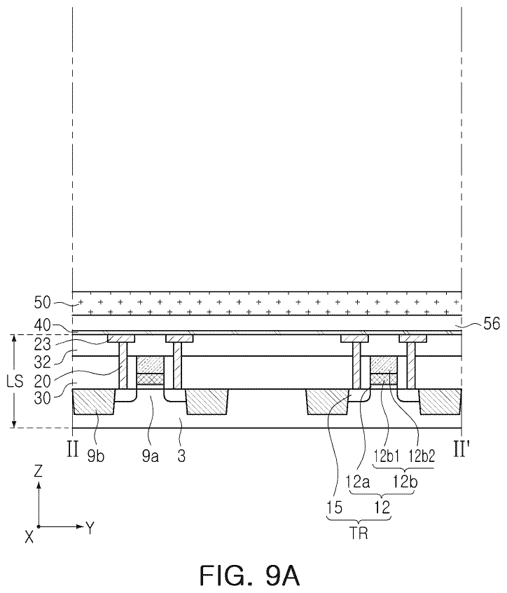

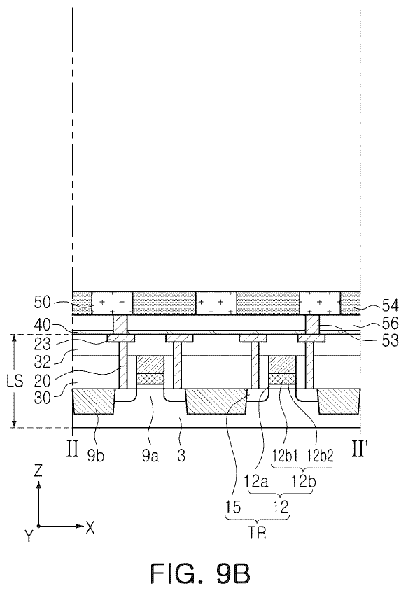

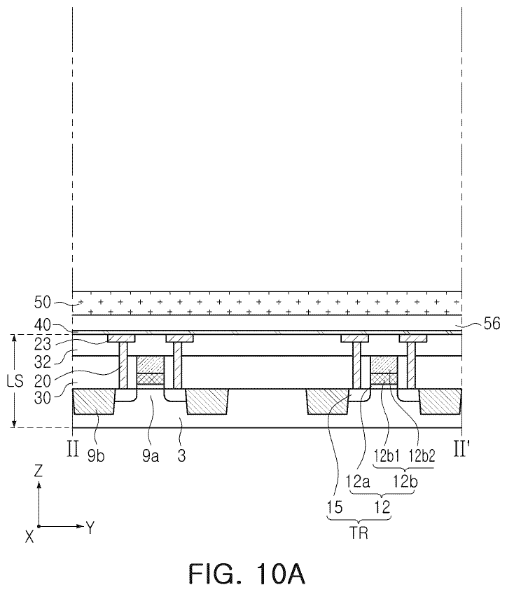

Referring to FIGS. 9A and 9B, an intermediate insulating layer 54 may be formed on at least one side of the bit line 50.

After forming an insulating material to fill the openings OP1 according to FIGS. 8A and 8B and covering the upper surface of the bit line 50, a planarization process may be performed on the insulating material. Accordingly, the intermediate insulating layers 54 having an upper surface substantially coplanar with upper surfaces of the bit lines 50 may be formed. The intermediate insulating layers 54 may extend in a Y-direction on at least one side of the bit line 50 and may be spaced apart from each other in the X-direction.

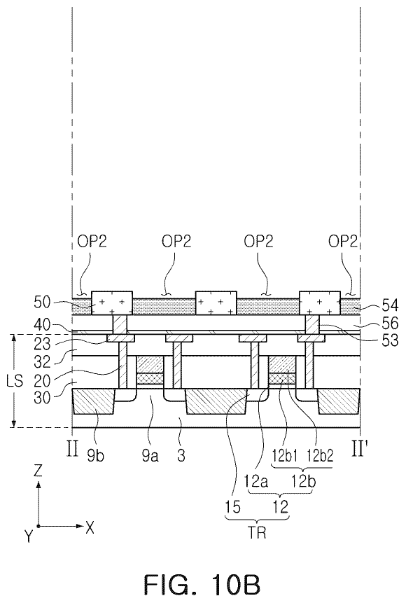

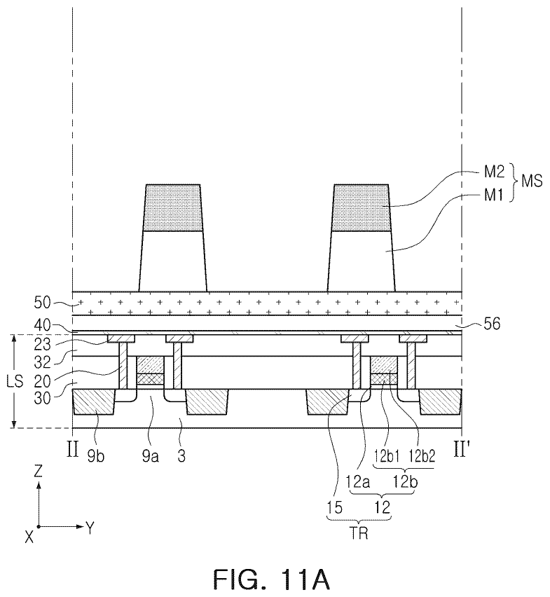

Referring to FIGS. 10A and 10B, a portion of the intermediate insulating layer 54 may be removed to expose at least a portion of side surfaces of the bit lines 50.

A predetermined mask layer may be formed on the bit line 50 and the intermediate insulating layer 54 according to FIGS. 9A and 9B. Thereafter, using the mask layer, openings OP2 that allows at least a portion of a side surface of the bit line 50 to be exposed in the X-direction may be formed.

An upper region of the intermediate insulating layer 54 may be removed by means of the openings OP2.

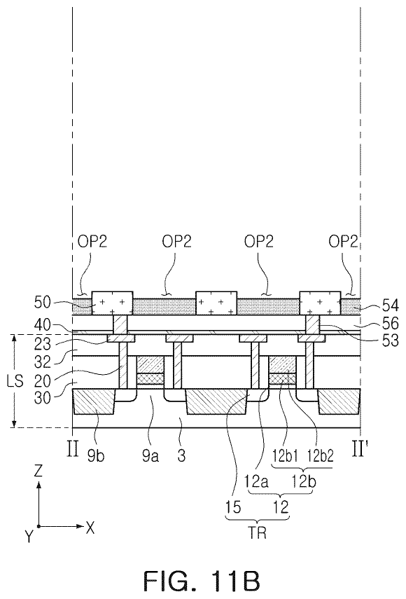

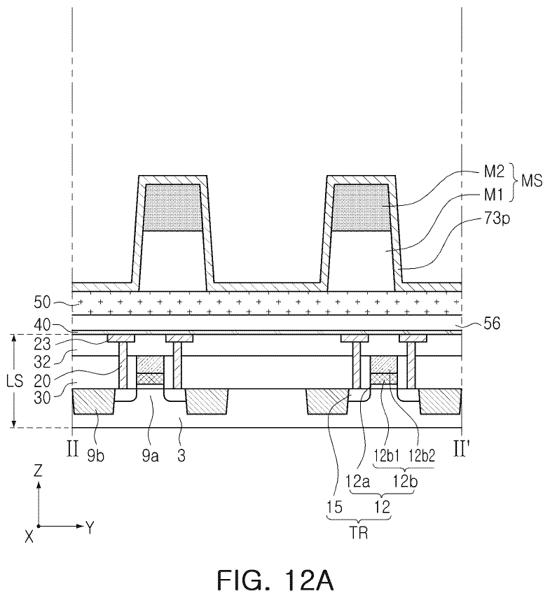

Referring to FIGS. 11A and 11B, mold structures MS may be formed on the bit lines 50, respectively.

A lower insulating material and an upper insulating material may be sequentially stacked to cover the bit lines 50 and the intermediate insulating layers 54, and then the lower insulating material and the upper insulating material may be patterned to form lower mold layers M1 and upper mold layers M2. The lower mold layer M1 and the upper mold layer M2 may include silicon oxide, silicon nitride, silicon oxynitride, or a combination thereof.

The mold structures MS may extend on the bit lines 50 in the X-direction and may be spaced apart from each other in the Y-direction. In at least one example embodiment, each of the mold structure MS may have a tapered shape in which a horizontal width thereof in the Y-direction decreases as it moves up, but the present inventive concepts is not limited thereto.

In at least one example embodiment, the lower mold layer M1 and the upper mold layer M2 may include different materials. For example, the lower mold layer M1 may include silicon oxide, and the upper mold layer M2 may include silicon nitride. In some example embodiments, the lower mold layer M1 and the upper mold layer M2 may include the same material and may be integrally formed.

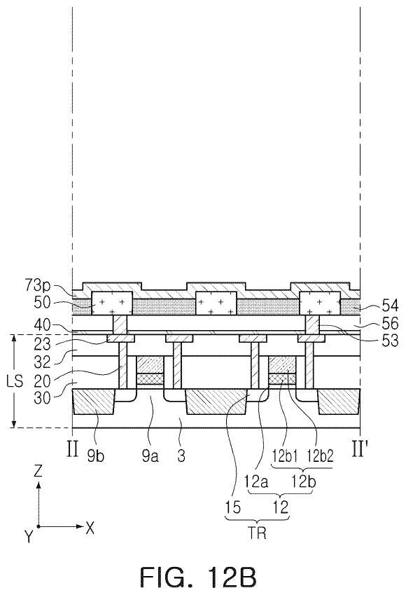

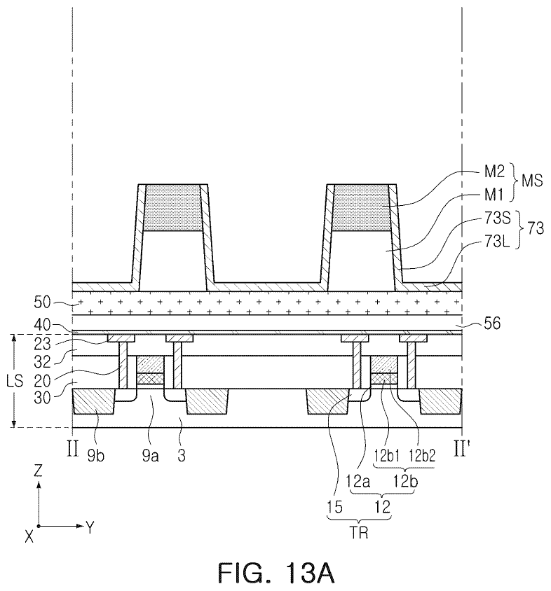

Referring to FIGS. 12A and 12B, a channel material layer 73p may be formed.

The channel material layer 73p may be formed to cover the bit lines 50, the intermediate insulating layers 54, and the mold structures MS. For example, the channel material layer 73p may conformally cover the mold structures MS.

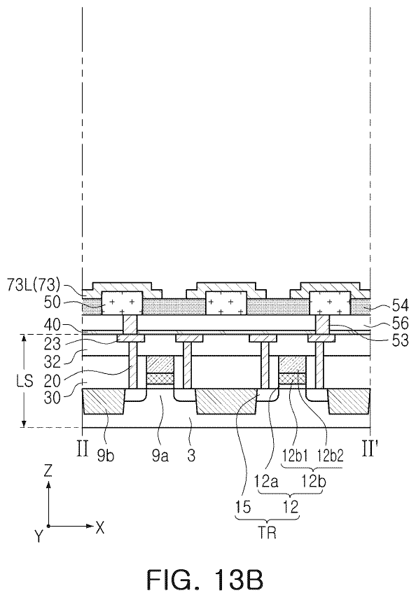

Referring to FIGS. 13A and 13B, the channel material layer 73p may be patterned.

The channel material layer 73p may be patterned by means of an etching process, such as a chemical and/or mechanical etching process. Accordingly, an upper surface of the mold structure MS and an upper surface of the middle insulating layer 54 may be partially exposed, and a channel structure 73 may be formed. The channel structure 73 may include a lower portion 73L in contact with the bit line 50 and extending in the horizontal direction, and an upper portion 73S extending upwardly along a side surface of the mold structure MS.

As described with reference to FIGS. 3A and 3B, the lower portion 73L may include a portion 73La covering the upper surface of the bit line 50 and portions 73 Lb and 73Lc covering the side surface of the bit line 50 on the intermediate insulating layer 54.

In at least one embodiment, the upper portion 73S may extend in a direction other than a vertical direction (Z-direction), but the present inventive concepts are not limited thereto. In some embodiments, the upper portion 73S may extend in the vertical direction. The channel structures 73 may be spaced apart from each other in the X-direction and the Y-direction (see FIG. 1).

The etching process may be performed by forming a predetermined mask layer on the channel material layer 73p.

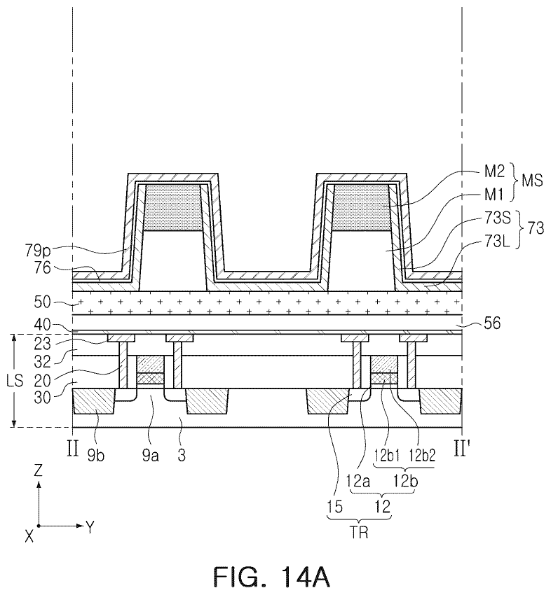

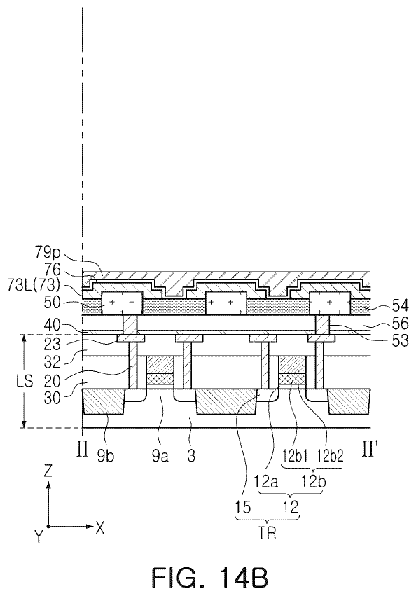

Referring to FIGS. 14A and 14B, a dielectric material layer 76 and a conductive layer 79p may be formed.

The dielectric material layer 76 may be formed conformally along the channel structures 73, the intermediate insulating layers 54 and the mold structures MS. The conductive layer 79p may cover the dielectric material layer 76.

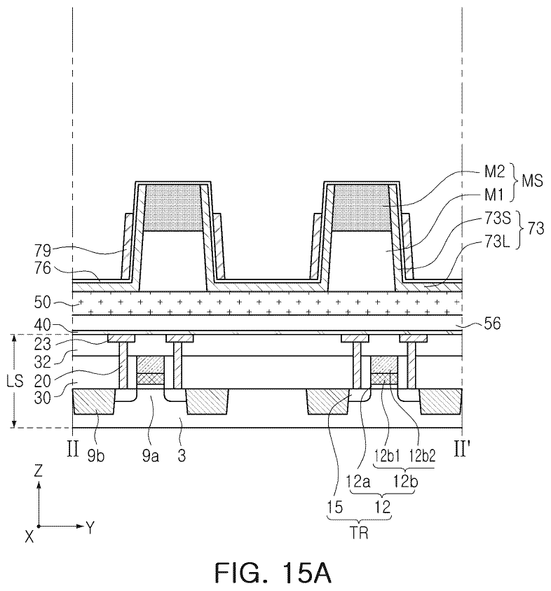

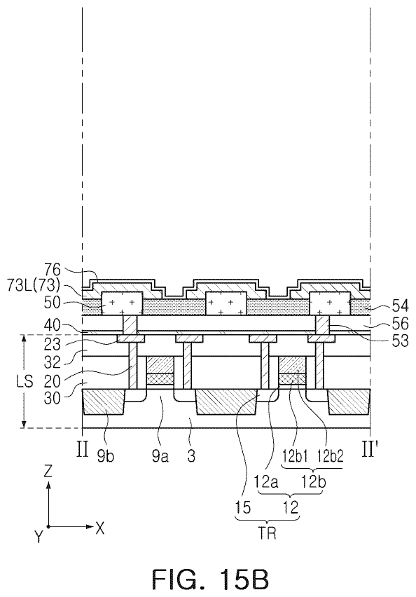

Referring to FIGS. 15A and 15B, the conductive layer 79p may be etched by means of an anisotropic etching process to form word lines 79.

In a plan view, the word lines 79 may intersect the bit lines 50. For example, the word lines 79 may be disposed on the side surfaces of the mold structures MS to extend in the X-direction, and may be spaced apart from each other in the Y-direction.

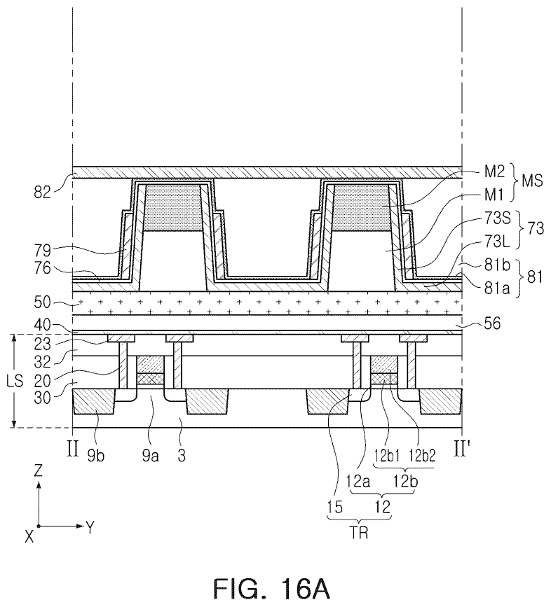

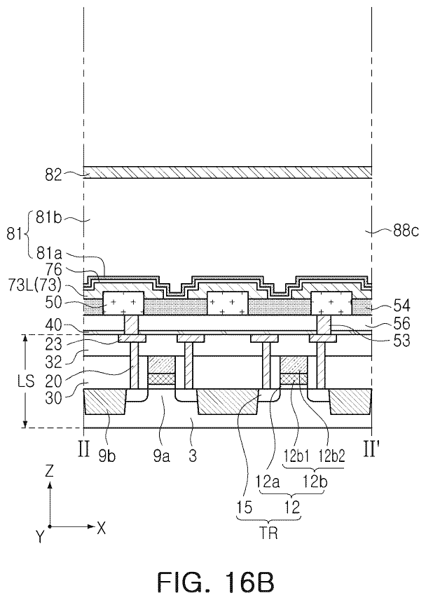

Referring to FIGS. 16A to 16B, an upper insulating structure 81 and an upper capping layer 82 may be formed.

The upper insulation structure 81 may include a first upper insulation layer 81a and a second upper insulation layer 81b. The first upper insulating layer 81a may be conformally formed along the bit lines 50, the intermediate insulating layers 54, the channel structures 73, the dielectric structures 76 and the word lines 79. The second upper insulating layer 81b may be formed by depositing an insulating material to cover the first upper insulating layer 81a and then planarizing the insulating material to expose an upper surface of the first upper insulating layer 81a. The upper insulating structures 81 may extend in the X-direction and may be spaced apart from each other in the Y-direction. The upper insulating structures 81 may be alternately disposed with the mold structures MS in the Y-direction.

The upper capping layer 82 may cover an upper surface of the upper insulating structure 81.

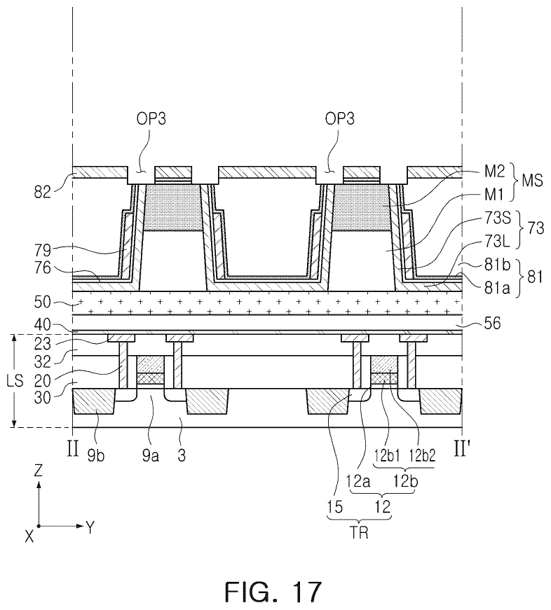

Referring to FIG. 17, an upper capping layer 82 may be etched by means of an anisotropic etching process, and an opening OP3 exposing a channel structure 73 may be formed.

The opening OP3 may expose an upper surface of the vertical channel portion 73S. The opening OP3 may also expose the upper mold layer M2, the dielectric structure 76 and the upper insulating structure 81.

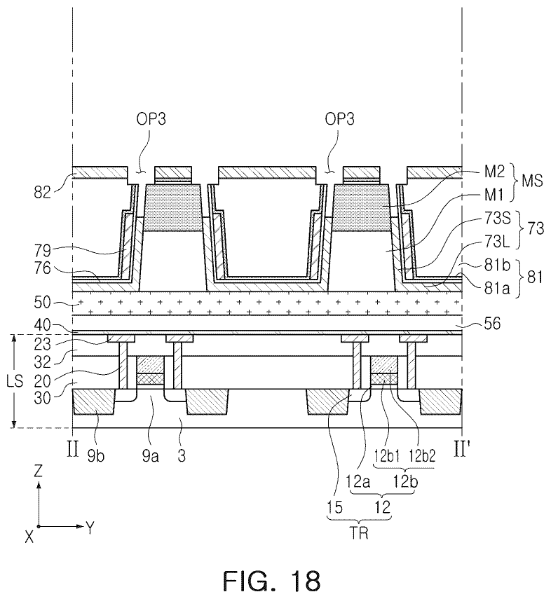

Referring to FIG. 18, the channel structure 73 may be selectively etched.

Etching the channel structure 73 may include performing a first wet etching process. An etchant may flow into the opening OP3, and an upper part of an upper portion 73S of the channel structure 73 may be selectively etched by the etchant. In at least one example embodiment, an upper surface of the etched upper portion 73S may be above an upper surface of the lower mold layer M1. A side surface the dielectric structure 76 may be partially exposed by means of the first wet etching process.

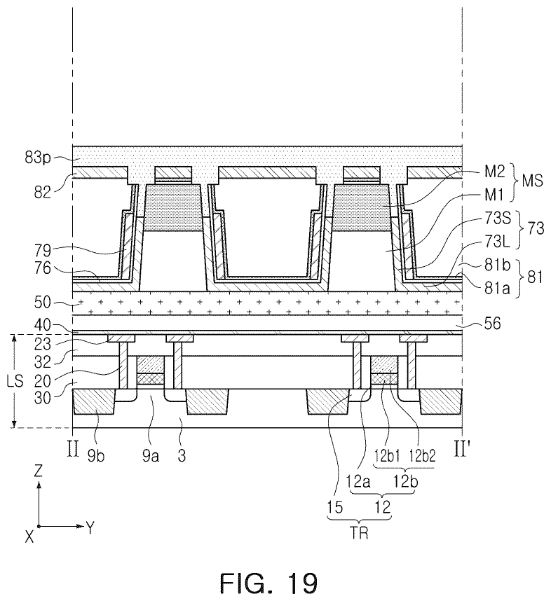

Referring to FIG. 19, a conductive layer 83p may be formed to fill the opening OP3 and cover an upper capping layer 82.

The conductive layer 83p may be in contact with the upper surface of the upper portion 73S. The conductive layer 83p may also be in partial contact with a side surface of the vertical channel portion 73S. The conductive layer 83p may be electrically connected to a bit line 50 through a channel structure 73. In an example, the conductive layer 83p may include a metal layer and a barrier layer.

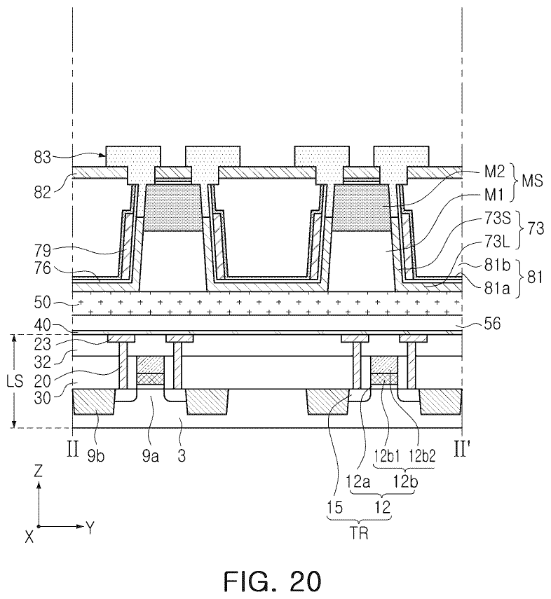

Referring to FIG. 20, the conductive layer 83p may be patterned to form the landing pad structure 83.

Referring to FIG. 2 together, after depositing an insulating material to cover the landing pad structure 83, the insulating material may be planarized to expose an upper surface of the landing pad structure 83, thereby forming an insulating pattern 86. The insulating pattern 86 may be disposed on the same level as that of the landing pad structures 83 and may electrically insulate the landing pad structures 83 from each other. The mold structure MS, the channel structure 73, the dielectric structure 76, the word line 79, the upper insulation structures 81, the upper capping layer 82, the landing pad structure 83, and the insulation patterns 86 may form an upper structure US.

An information storage structure 87 may be formed on the upper structure US to manufacture the semiconductor device 100. As described with reference to FIGS. 1 to 3B, the information storage structure 87 may include first electrodes 88a electrically connected to and in contact with the landing pad structure 83, the second electrode 88c on the first electrodes 88a, and the dielectric layer 88b between the first electrodes 88a and the second electrode 88c.

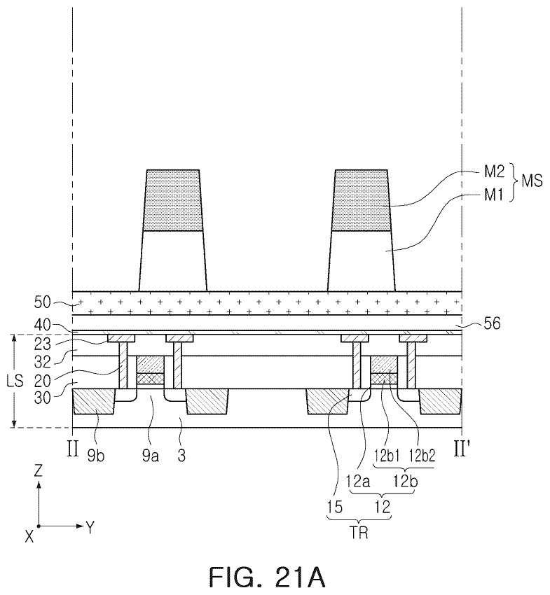

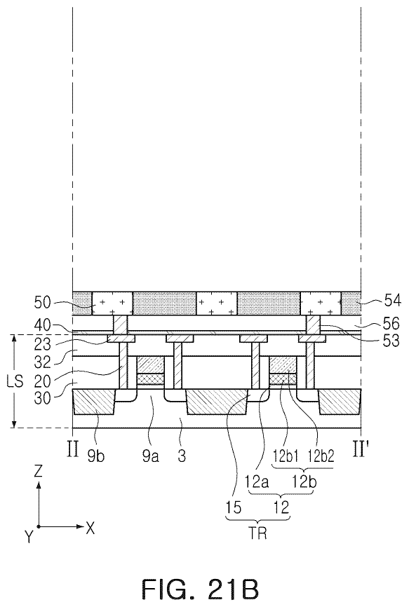

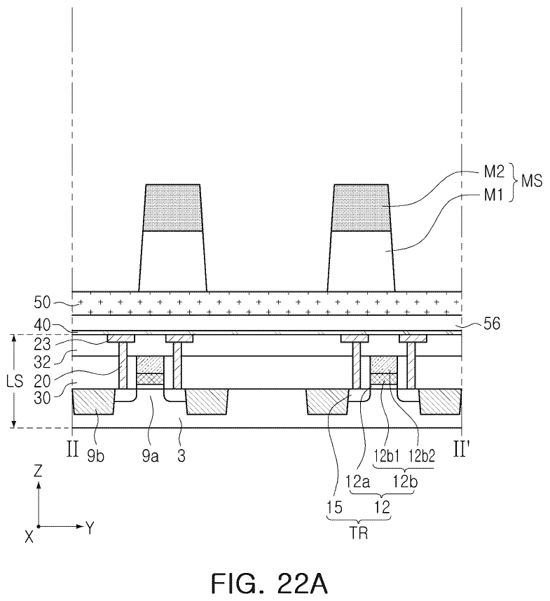

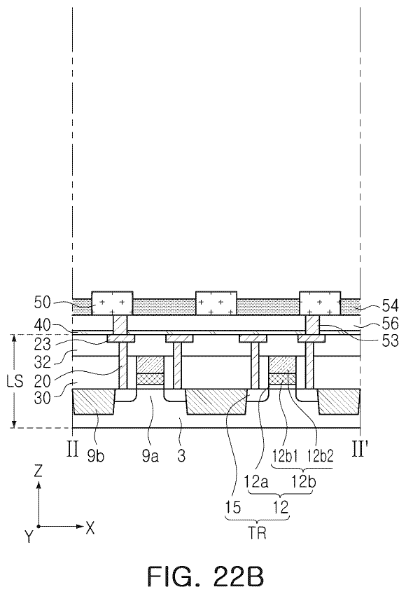

FIGS. 21A to 22B are vertical cross-sectional views illustrated according to a process order to explain a method of manufacturing a semiconductor device according to at least one example embodiment. FIGS. 21A to 22B may be process diagrams for a separate manufacturing method that is different from the semiconductor device manufacturing method described with reference to FIGS. 7A to 20. FIGS. 21A and 22A are vertical cross-sectional views corresponding to FIG. 2, while FIGS. 21B and 22B are vertical cross-sectional views corresponding to FIG. 3A.

Meanwhile, FIGS. 21A and 21B may be process diagrams following FIGS. 9A and 9B, respectively. In addition, the process of FIGS. 22A and 22B may be followed by the process described with reference to FIGS. 12A and 12B, respectively.

Referring to FIGS. 21A and 21B, after forming the intermediate insulating layer 54 according to FIGS. 9A and 9B, the mold structure MS may be formed on the bit line 50.

After sequentially stacking the lower insulating material and the upper insulating material to cover the bit line 50 and the middle insulating layer 54, the lower insulating material and the upper insulating material may be patterned to form the lower mold layer M1 and the upper mold layer M2. In this process embodiment, the upper insulating material may be formed to be thicker than the upper insulating material described with reference to FIGS. 11A and 11B.

Referring to FIGS. 22A and 22B, a portion of the intermediate insulating layer 54 and the mold structure MS may be removed.

By means of an etching process, the upper region of the upper mold layer M2 of the mold structure MS may be removed, and a portion of the middle insulating layer 54 may also be removed at the same time so that a portion of the side surface of the bit line 50 is exposed.

The etching process may be performed by forming a predetermined mask layer on the bit line 50, the intermediate insulating layer 54 and the mold structure MS.

Thereafter, as described with reference to FIGS. 12A and 12B, the channel material layer 73p may be formed to conformally cover the bit lines 50, the intermediate insulating layers 54 and the mold structures MS.

Similarly, the semiconductor device 100 may be manufactured by forming the upper structure US and the information storage structure 87 on the upper structure US, in the same manner as described with reference to FIGS. 13A to 20.

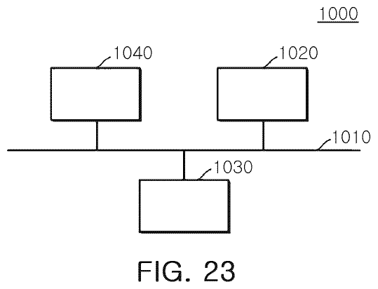

FIG. 23 is a schematic of an electronic device according to at least one embodiment.

Referring to FIG. 23, the electronic device 1000 includes one or more electronic device components, including a processor (e.g., processing circuitry) 1020 and a memory 1030 that are communicatively coupled together via a bus 1010.

The processing circuitry 1020 may include, may be included in, and/or may be implemented by one or more instances of processing circuitry such as hardware including logic circuits, a hardware/software combination such as a processor executing software; or a combination thereof. For example, the processing circuitry 1020 may include, but is not limited to, a central processing unit (CPU), an application processor (AP), an arithmetic logic unit (ALU), a graphic processing unit (GPU), a digital signal processor, a microcomputer, a field programmable gate array (FPGA), a System-on-Chip (SoC) a programmable logic unit, a microprocessor, or an application-specific integrated circuit (ASIC), etc. In some example embodiments, the memory 1030 may include a non-transitory computer readable storage device, for example a solid state drive (SSD), storing a program of instructions, and the processing circuitry 1020 may be configured to execute the program of instructions to implement the functionality of the electronic device 1000.

In some example embodiments, the electronic device 1000 may include one or more additional components 1040, coupled to bus 1010, which may include, for example, a power supply, a light sensor, a light-emitting device, any combination thereof, and/or the like. In some example embodiments, one or more of the processing circuitry 1020, memory 1030, or one or more additional components 1040 may include any of the semiconductor devices according to any of the example embodiments described with reference to, e.g., FIGS. 1-6, and/or the like.

According to embodiments of the present inventive concepts, a semiconductor device with advantageously enhanced on current may be provided by increasing a contact area between a bit line and a channel structure.

Specifically, a semiconductor device of the present inventive concepts may include a channel structure in contact with not only an upper surface of a bit line but also at least a portion of a side surface of the bit line, thereby advantageously enhancing an on current. While example embodiments have been shown and described above, it will be apparent to those skilled in the art that modifications and variations could be made without departing from the scope of the present inventive concepts as defined by the appended claims.

What is claimed is:

1. A semiconductor device, comprising
a bit line extending in a first horizontal direction;
an intermediate insulating layer on at least one side of the bit line and extending in the first horizontal direction such that the intermediate insulating layer is in contact with at least a portion of a side surface of the bit line;
a channel structure comprising a lower portion and an upper portion, the lower portion of the channel structure on the bit line and the intermediate insulating layer, and the upper portion of the channel structure extending upwardly from one end of the lower portion; and
a word line on the lower portion of the channel structure and extending across the bit line in a second horizontal direction, the second horizontal direction intersecting the first horizontal direction,
wherein the lower portion of the channel structure comprises a first portion covering an upper surface of the bit line and a second portion extending downwardly from one end of the first portion and covering at least a portion of the side surface of the bit line on the intermediate insulating layer.

2. The semiconductor device of claim 1, wherein the lower portion of the channel structure further comprises a third portion extending in the second horizontal direction from one end of the second portion along an upper surface of the intermediate insulating layer.

3. The semiconductor device of claim 1, wherein at least a portion of the side surface of the bit line are inclined with respect to a lower surface of the bit line.

4. The semiconductor device of claim 1, wherein a thickness of the bit line in the second horizontal direction increases from the upper surface of the bit line to a lower surface of the bit line.

5. The semiconductor device of claim 1, wherein at least one of a lower surface or an upper surface of the intermediate insulating layer has a downwardly curved shape.

6. The semiconductor device of claim 1, wherein a lower surface of the intermediate insulating layer is on a level lower than a lower surface of the bit line.

7. The semiconductor device of claim 1, wherein the intermediate insulating layer is adjacent to a lower region of the bit line such that the intermediate insulating layer is in contact with a side surface of the lower region of the bit line.

8. The semiconductor device of claim 1, wherein the lower portion of the channel structure further comprises a third portion extending in the second horizontal direction from one end of the second portion along an upper surface of the intermediate insulating layer and having an end portion on the intermediate insulating layer, and
the intermediate insulating layer has a concave portion adjacent to the end portion of the third portion and concave downward in an upper region of the intermediate insulating layer.

9. The semiconductor device of claim 8, further comprising:
a dielectric structure extending in the second horizontal direction across the bit line and the intermediate insulating layer on the bit line and the intermediate insulating layer,
wherein the dielectric structure covers an external side surface of the lower portion of the channel structure and a surface of the concave portion of the intermediate insulating layer.

10. The semiconductor device of claim 9, wherein the concave portion of the intermediate insulating layer extends in the first horizontal direction.

11. The semiconductor device of claim 1, wherein the intermediate insulating layer is adjacent to the bit line such that the intermediate insulating layer is in contact with a side surface of the bit line in an upper region of the bit line.

12. The semiconductor device of claim 1, further comprising:
a dielectric structure extending in the second horizontal direction across the bit line and the intermediate insulating layer on the bit line and the intermediate insulating layer,
wherein the dielectric structure covers an external surface of the lower portion of the channel structure and at least a portion of an upper surface of the intermediate insulating layer.

13. The semiconductor device of claim 12, wherein the dielectric structure extends upwardly from the one end of the lower portion of the channel structure between the upper portion of the channel structure and the word line.

14. A semiconductor device, comprising:
a bit line extending in a first horizontal direction;
an intermediate insulating layer extending in the first horizontal direction from at least one side of the bit line and having an upper surface at a level lower than an upper surface of the bit line;
a channel structure comprising a lower portion and an upper portion, the lower portion of the channel structure on the bit line and the intermediate insulating layer, and the upper portion of the channel structure extending upwardly from one end of the lower portion, the lower portion of the channel structure further comprising a first line portion covering the upper surface of the bit line, and a second line portion extending downwardly from one end of the first line portion and covering a side surface of the bit line on the intermediate insulating layer;
a word line on the lower portion of the channel structure and extending across the bit line in a second horizontal direction, the second horizontal direction intersecting the first horizontal direction; and
a dielectric structure extending in the second horizontal direction across the bit line and the intermediate insulating layer,
wherein the dielectric structure covers an external surface of the lower portion of the channel structure and at least a portion of an upper surface of the intermediate insulating layer.

15. The semiconductor device of claim 14, wherein at least a portion of the side surface of the bit line has an upwardly curved shape, and
the second line portion on the at least a portion of the side surface of the bit line has an upwardly curved shape.

16. The semiconductor device of claim 14, wherein the second line portion has an end portion on the intermediate insulating layer, and
the dielectric structure comprises
a first inclined portion on the side surface of the bit line; and
a second inclined portion on the end portion of the second line portion of the channel structure.

17. The semiconductor device of claim 14, wherein the intermediate insulating layer comprises silicon nitride.

18. The semiconductor device of claim 14, wherein the channel structure comprises an oxide semiconductor.

19. A semiconductor device, comprising:
a lower insulating layer;
a bit line on the lower insulating layer;
an intermediate insulating layer on a side surface of a lower region of the bit line;
a channel structure on the bit line;
a word line on the channel structure such that a side surface of the word line faces a side surface of the channel structure;
a dielectric structure between the word line and the channel structure; and
a pad structure on the channel structure,
wherein the bit line comprises a first conductive layer, a second conductive layer and a third conductive layer, sequentially stacked, and
the channel structure is in contact with an upper surface and a side surface of the third conductive layer.

20. The semiconductor device of claim 19, wherein a thickness of the third conductive layer is greater than a thickness of the first conductive layer,
the intermediate insulating layer is in contact with a side surface of the first conductive layer and a lower surface of the channel structure, and
the channel structure is spaced apart from the side surface of the first conductive layer.
